(19) United States
(12) Patent Application Publication
(10) Pub. No.: US 2026/0213497 A1
(43) Pub. Date: Jul. 23, 2026

(54) CURRENT-CONFINED MULTI-JUNCTION DIODE-LASER BAR

(71) Applicant: II-VI Delaware, Inc., Wilmington, DE (US)

(72) Inventors: Guoli LIU, Pleasanton, CA (US); Jingwei LI, Livermore, CA (US); Zuntu XU, Campbell, CA (US); Sami LEHKONEN, San Jose, CA (US)

(73) Assignee: II-VI Delaware, Inc., Wilmington, DE (US)

(21) Appl. No.: 19/456,754

(22) Filed: Jan. 22, 2026

Related U.S. Application Data
(60) Provisional application No. 63/748,500, filed on Jan. 23, 2025.

(51) Int. Cl. H01S 5/40; H01S 5/20

(52) U.S. Cl. CPC H01S 5/4031; H01S 5/2054

(57) ABSTRACT

An edge-emitting diode-laser bar comprises a plurality of diode-laser junctions. The diode-laser junctions are vertically arranged and separated by tunneling junctions. Each diode-laser junction is overlaid by a current confinement layer. Together, these current confinement layers laterally constrain current flow through emitters in this semiconductor structure. Active regions in vertically-aligned emitters have the same current density. Vertically-aligned emitters have the same threshold current for lasing and the same optical output power. A plurality of such diode-laser bars is assembled into a high-output-power high-brightness vertical stack.

### CROSS-REFERENCE TO RELATED APPLICATIONS

This application claims the benefit of US Provisional Ser. No. 63/748,500, filed 23 Jan. 2025, the entire contents of which is incorporated herein by reference.

### TECHNICAL FIELD OF THE INVENTION

The present invention relates in general to the semiconductor structure of diode-laser bars. The invention relates in particular to the semiconductor structure of edge-emitting diode-laser bars having multiple junctions.

### DISCUSSION OF BACKGROUND ART

Diode lasers are efficient devices for converting electrical power into coherent optical power. In this respect, they are the most efficient laser devices. Laser radiation generated by diode lasers may be used directly in industrial processes, such as welding, annealing, hardening, or drying. Alternatively, laser radiation generated by diode lasers may be used to energize other lasers, which essentially convert the diode-laser radiation into brighter laser beams having different wavelengths.

Currently, there is significant investment and effort in fusion as a future carbon-free clean energy source. First fusion ignition was achieved at Lawrence Livermore National Laboratory (LLNL) in December 2022. LLNL uses approximately 2 mega Joules of ultraviolet laser energy to drive inertial-confinement fusion. The ultraviolet laser radiation is generated by flashlamp-pumped solid-state lasers. The flashlamps convert electrical power into useful optical power for pumping with an efficiency as low as 2%. This low efficiency is an obstacle to achieving fusion engineering break-even. Diode-laser-pumped solid-state lasers would potentially have more than 50% wall-plug efficiency, compared to 0.5% with flashlamp pumping.

Generally, diode lasers are either surface emitting or edge-emitting. An edge-emitting diode laser has a waveguide resonator that is typically between a few hundred micrometers and a few millimeters long. A thin active region is sandwiched between p-type and n-type semiconductor material. Optical waveguiding is provided by thin core layers and cladding layers incorporated into the semiconductor material on each side of the active region. Light is generated in the active region by the recombination of electrons and holes injected, respectively, from the n-type and p-type material. The active region comprises one or more quantum wells that further confine the electrons and holes for efficient recombination. Opposite end facets define the resonator length of the edge emitter. One of these facets is reflective and the other is partially reflective. Laser radiation is emitted through the partially-reflective facet when the injected current exceeds a threshold.

For high-power applications, diode-laser bars having a plurality of edge emitters provide a convenient way to scale optical power. Individual edge emitters are located on a common substrate and are arranged in a “horizontal” linear array. Typically, the substrate is made of an n-type material. The various layers forming the diode-laser bar are epitaxially grown from a bottom-most “n-side” to a top-most “p-side”. The diode-laser bar is usually soldered “p-side down” onto either a heat sink or a submount that has a coefficient of thermal expansion close to that of the semiconductor material. In operation, waste heat is conducted away through the heat sink or submount. In some applications, heat load and thermal stresses can be substantially reduced by operating at a lower duty cycle by pulsed current injection, which is known as “quasi-continuous wave” operation.

For further power scaling, a plurality of diode-laser bars and their submounts may be stacked together “vertically” to make a two-dimensional array of individual edge emitters. Diode-laser bars arranged in this manner are commonly referred to as a “vertical stack”. To maximize brightness, the bars would have minimum emitter-to-emitter pitch, the stack would have minimum bar-to-bar pitch, and the stack would be operated in a quasi-continuous wave mode.

Another way to scale power and brightness is to form two active regions during epitaxial growth, thereby forming a pair of emitters. Each active region is sandwiched between p-type and n-type layers. The n-type layers of the top emitter are separated from the p-type layers of the bottom emitter by a tunneling junction. The tunneling junction comprises highly doped p-type and n-type layers, allowing for stable serial electrical connection between the two emitters, with minimal electrical resistance. A diode-laser bar then becomes a linear array of pairs of individual emitters. Ideally, such “double-junction” diode-laser bars provide twice the optical power for a given injection current, and the brightness of a stack thereof is also approximately doubled.

### SUMMARY OF THE INVENTION

Current spreading within the semiconductor structure becomes a limitation for power scaling in double-junction diode devices. To maximize efficiency, current may be injected only proximate to each pair of emitters: for example, by an anode electrode that is adjacent to the top-most emitter and has the same width. A more practical and effective solution is to spatially confine the current within the semiconductor structure: for example, by including an electrical insulator within the otherwise p-type layers, which is omitted in the area between the anode electrode and the top-most emitter.

The inventors recognized that while these solutions provide sufficient current confinement for the top-most emitter, current spreading will significantly reduce the current density in the bottom-most emitter. This lateral current spreading increases with current and also with the resistivity of layers in the semiconductor structure. The lower current density reduces the optical power from the bottom-most emitter, which will also generate less heat and therefore may be shifted in wavelength with respect to the top-most emitter. The overall result is a less-efficient diode-laser bar, producing laser radiation having a broader spectral width. This is undesirable for pumping solid-state lasers, such as the lasers in the LLNL National Ignition Facility (NIF), which have neodymium-doped glass gain slabs with a definite absorption bandwidth. Any portion of the pump laser radiation outside the absorption bandwidth would mostly be wasted and would not contribute to optical gain in a slab.

In one aspect, an edge-emitting diode-laser bar in accordance with the present invention comprises a plurality of n-type layers, a plurality of p-type layers, and a plurality of active regions. Each active region is sandwiched between an adjacent n-type layer and an adjacent p-type layer to form one of a plurality of diode-laser junctions. The diode-laser junctions are vertically arranged on a substrate to form a semiconductor structure. The diode-laser bar further comprises at least one tunneling junction, arranged such that adjacent diode-laser junctions have a tunneling junction located therebetween. The p-type layer of each diode-laser junction is overlaid by a current confinement layer. The current confinement layers laterally constrain current flow through the semiconductor structure.

In another aspect, a vertical stack in accordance with the present invention comprises a plurality of such edge-emitting diode-laser bars. Each of the edge-emitting diode-laser bars is sandwiched between spacers made of a material that is thermally conductive and electrically conductive.

### BRIEF DESCRIPTION OF THE DRAWINGS

The accompanying drawings, which are incorporated in and constitute a part of the specification, schematically illustrate a preferred embodiment of the present invention, and together with the general description given above and the detailed description of the preferred embodiment given below, serve to explain principles of the present invention.

FIG. 1A is a cross-sectional view and FIG. 1B is a front view schematically illustrating details of an edge-emitting diode-laser bar having a single-junction.

FIG. 2 is a perspective view schematically illustrating an edge-emitting diode-laser bar having a double-junction in accordance with the present invention.

FIG. 3 is a perspective view schematically illustrating a stack of the edge-emitting diode-laser bars of FIG. 2.

FIG. 4 is a cross-sectional view schematically illustrating the semiconductor structure of a prior-art double-junction diode laser.

FIG. 5 is a cross-sectional view schematically illustrating one embodiment of semiconduction structure for a double-junction diode laser in accordance with the present invention, including a current confinement layer located between the two junctions.

FIGS. 6A-6C schematically illustrate a method of making the double-junction diode laser of FIG. 5 in accordance with the present invention.

FIGS. 7A-7C and 8A-8C schematically illustrate methods of making another embodiment of double-junction diode laser in accordance with the present invention.

FIGS. 9A-9C schematically illustrate a method of making yet another embodiment of double-junction diode laser in accordance with the present invention.

FIGS. 10A, 10B, 11A, and 11B are graphs illustrating the performance of an edge-emitting diode-laser bar having a single-junction semiconductor structure and one row of emitters.

FIGS. 12A and 12B are graphs illustrating the performance of an edge emitting diode-laser bar having the double-junction semiconductor structure of FIG. 4 and two rows of emitters.

FIGS. 13A, 13B, 14A, 14B, 15A, 15B, 16A, 16B, 17A, 17B, 18A, and 18B are graphs illustrating the performance of an edge-emitting diode-laser bar having the double-junction semiconductor structure of FIG. 5 and two rows of emitters, in accordance with the present invention.

### DETAILED DESCRIPTION OF THE INVENTION

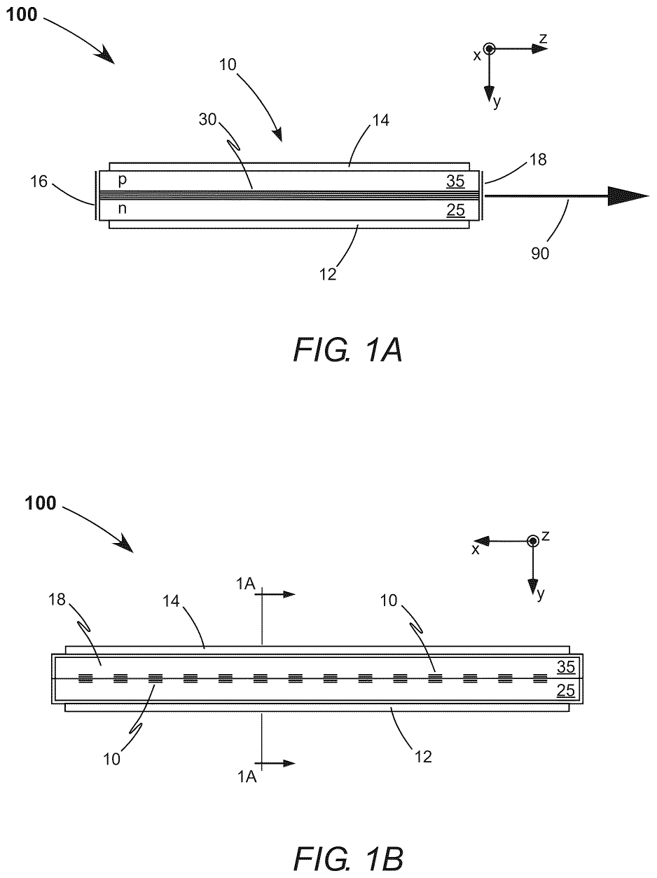

Referring now to the drawings, wherein like components are designated by like numerals, FIG. 1A is a cross-sectional view and FIG. 1B is a front view schematically illustrating an edge-emitting diode-laser bar 100. The cross-section of FIG. 1A is selected to include one individual emitter 10 of diode-laser bar 100 that produces output laser radiation 90. Diode-laser bar 100 comprises an active region 30 sandwiched between n-type layer 25 and p-type layer 35. Active region 30 may include a plurality of quantum wells that confine electrons and holes during operation. Layers 25 and 35 provide electrons and holes, respectively, to active region 30 in operation. Layers 25 and 35 cooperatively provide optical waveguiding for laser radiation generated in active region 30. Each of layers 25 and 35 may include core and cladding layers that are not depicted in the drawings.

Active region 30, n-type layer 25, and p-type layer 35 are made of a common semiconductor material, such as gallium arsenide (GaAs), indium phosphide (InP), or gallium nitride (GaN). GaAs is used in the examples presented herein. Other materials may be selected to produce laser radiation at different wavelengths. The quantum well heterostructure of active region 30 comprises layers of In(Al)GaAs and AlGaAs. The n-type and p-type materials are selectively doped to provide an excess of electrons in n-type layer 25 and an excess of holes in p-type layer 35. For example, n-type doping with silicon, tin, or sulfur, and p-type doping with carbon or zinc.

Diode-laser bar 100 also includes a cathode electrode 12, an anode electrode 14, a high-reflection facet 16, and a partially-reflective facet 18. Electrodes 12 and 14 may be metal layers deposited on the semiconductor surfaces.

The resonator length of emitter 10 is defined by the distance between facets 16 and 18. High-reflection facet 16 may have a reflectivity exceeding 80%, exceeding 95%, or even exceeding 99% at the lasing wavelength. Partially-reflective facet 18 may have reflectivity of less than 30% or even less than 10% at the lasing wavelength. These reflectivities may be provided by multi-layer dielectric coatings on facets 16 and 18. In some embodiments, partially reflective facet 18 is uncoated and provides a Fresnel reflection from the as-cleaved or as-polished semiconductor material. For GaAs, the Fresnel reflectivity would be approximately 30%.

In other embodiments (not depicted), one or both of facets 16 and 18 may be anti-reflection coated, and the resonator of emitter 10 has one or two external mirrors. External mirrors may have multi-layer dielectric coatings or may be volume Bragg gratings. The resonator length of emitter 10 is defined by the distance between the end mirrors, whether they be facets or external mirrors.

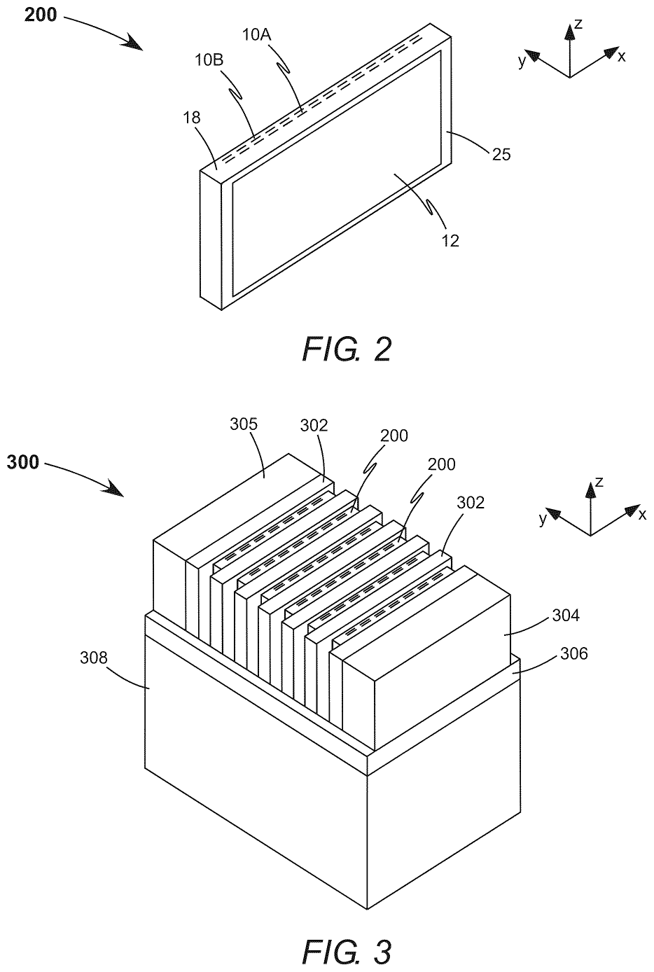

FIG. 2 is a perspective view schematically illustrating an edge-emitting diode-laser bar 200 in accordance with the present invention. Diode-laser bar 200 is similar to diode-laser bar 100, but has a double-junction structure. Pairs of individual emitters 10A and 10B are linearly arranged in the plane of partially reflective facet 18. All emitters 10A are arranged in a row and all emitters 10B are arranged in a parallel row. FIG. 2 depicts 14 pairs of emitters; however, this number may be chosen according to requirements of the specific application. For example, there may be between 5 and 30 pairs per bar (inclusive), which means 10 to 60 individual emitters per bar. By way of example, bars having 12, 18, or 24 pairs would be practical for high-power pumping of solid-state lasers.

FIG. 3 is a perspective view schematically illustrating a stack 300 of diode-laser bars 200 in accordance with the present invention. FIG. 3 depicts 6 diode-laser bars 200, but this number may be chosen according to the application. For example, there may be between 2 and 60 bars in a stack (inclusive). A stack of 50 bars, by way of example, would be practical for a very high-power application. Each diode-laser bar 200 is sandwiched between two spacers 302 that are made of a thermally conductive and electrically conductive material, such as copper tungstate (CuW) or copper diamond (Cu-Diamond).

Stack 300 may include optional end caps 304 and 305, to provide additional mechanical support and for convenient electrical connection. End caps 304 and 305 may be made of a metal, such as copper. Stack 300 may also include an optional submount 306 and an optional heatsink 308. Submount 306 may be made of an electrically-insulating material that is also thermally conductive, such as aluminum nitride (AlN), beryllium oxide (BeO), or diamond. Heatsink 308 may be made of a metal, such as copper or aluminum, and include channels for water cooling.

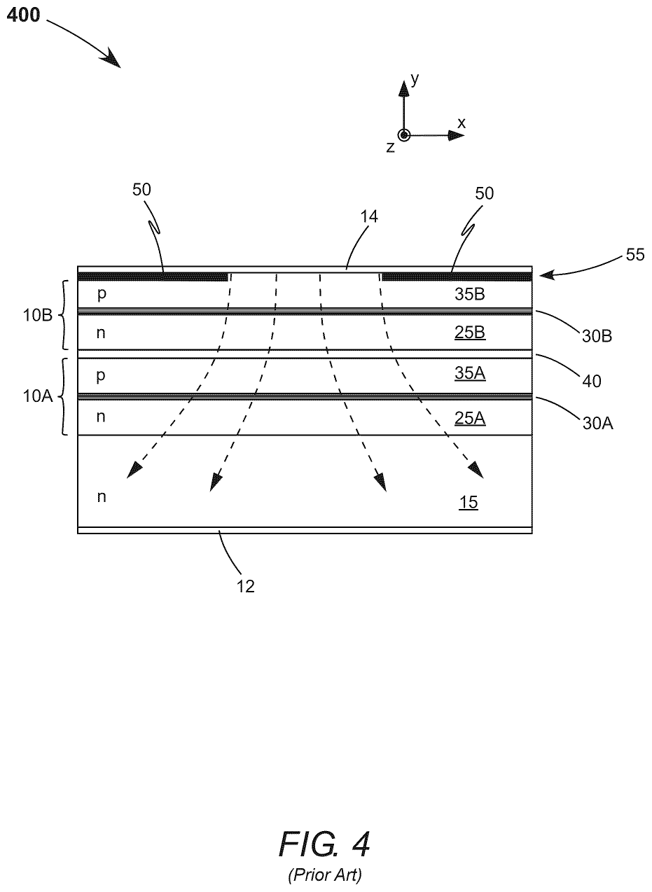

FIG. 4 is a cross-sectional view schematically illustrating the semiconductor structure 400 of a prior-art double-junction diode laser. The diode laser is grown on an n-type substrate 15. A bottom-most emitter 10A includes an n-type layer 25A, a p-type layer 35A, and an active region 30A therebetween. A top-most emitter 10B includes an n-type layer 25B, a p-type layer 35B, and an active region 30B therebetween. A tunneling junction 40 is located between p-type layer 35A of emitter 10A and n-type layer 25B of emitter 10B. A cathode electrode 12 is located on n-type substrate 15 and an anode electrode 14 is located on p-type layer 35B of emitter 10B.

Structure 400 includes a current confinement layer 55 that overlays emitter 10B. Current confinement layer 55 comprises sections 50 that are electrically insulating, with p-type material between electrically-insulating sections 50. Current confinement layer 55 only allows current to flow into p-type layer 35B between electrically-insulating sections 50. In operation at a given current, current confinement layer 55 defines the lateral widths of emitters 10A and 10B, which are essentially those portions of active regions 30A and 30B that exceed a threshold current density for lasing. Dashed lines in FIG. 4 schematically illustrate current spreading, which results in lower current density in active region 30A than in active region 30B. Lateral current spreading is generally more dramatic in n-type layer 25B than depicted in the drawing, due to high carrier mobility in this layer. Therefore, the difference in current density between the two active regions may be even greater than that suggested by the drawing.

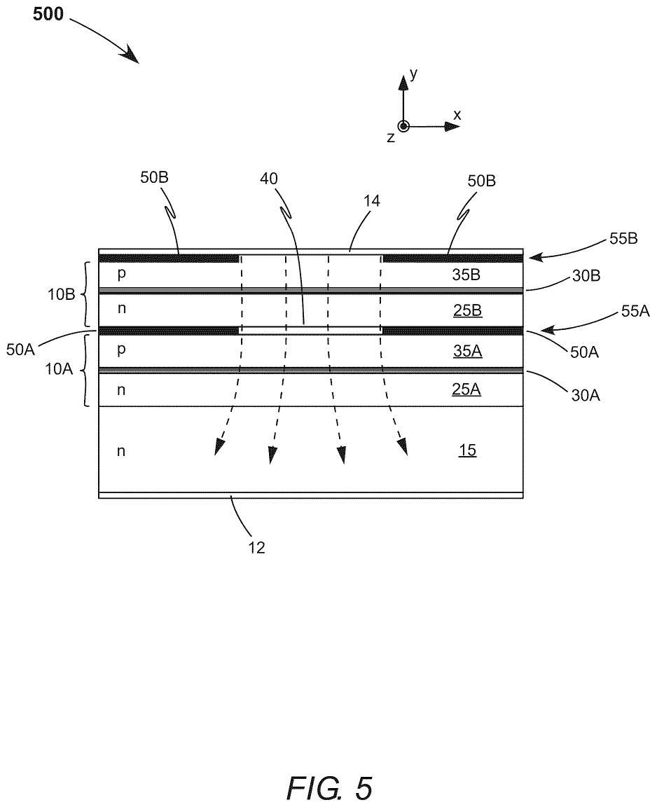

FIG. 5 is a cross-sectional view schematically illustrating a semiconductor structure 500 of an embodiment of double-junction diode laser in accordance with the present invention. Structure 500 includes bottom-most emitter 10A and top-most emitter 10B. Tunneling junction 40 and a current confinement layer 55A are located between p-type layer 35A of emitter 10A and n-type layer 25B of emitter 10B. Tunneling junction 40 is laterally located between sections 50A of current confinement layer 55A, which are electrically insulating. Therefore, current is only able to flow between the two emitters through tunneling junction 40. Current confinement layer 55A laterally constrains current flow between n-type layer 25B and p-type layer 35A. Together, current confinement layers 55A and 55B laterally constrain current flow through structure 500 in operation, as depicted by the dashed lines.

This spatial confinement of the current flow means that the current density is about the same in active regions 30A and 30B in operation. As demonstrated herein below, maintaining approximately the same current density in the two active regions means that both emitters will lase above the same threshold current, will provide about the same optical output power, and may provide laser radiation with about the same center wavelength.

Additional diode-laser junctions and their emitters may be added onto structure 500 to further scale power. Each of the plurality of diode-laser junctions would include an active region sandwiched between an adjacent n-type layer and an adjacent p-type layer. Adjacent diode-laser junctions would have a tunneling junction located therebetween. The same advantages of a common threshold current, a common output power, and a common center wavelength may be realized if each additional diode-laser junction is overlayed with a current confinement layer.

The gaps between sections 50A of current confinement layer 55A and between sections 50B of current confinement layer 55B are apertures for current flow. These gaps are about the same width in FIG. 5. For some semiconductor structures, the gap widths may be different in order to achieve the same current densities in active regions 30A and 30B. Gap widths may be selected based on the relative thicknesses of the various n-type and p-type layers, the resistivities thereof, and the current mobilities therein.

Two vertically-aligned emitters are depicted in FIG. 5, although there may be other emitters on substrate 15 that collectively form an edge-emitting diode-laser bar, such as diode-laser bar 200. Other emitters would be located on the left and right of the view. Emitters would be horizontally arranged in rows along a diode-laser bar, with each row corresponding to one diode-laser junction. Emitters in different rows would be vertically aligned in columns, as depicted. Laterally, emitter 10A is located below the gaps between sections 50A of confinement layer 55A, and emitter 10B is located below the gaps between sections 50B of confinement layer 55B. Gaps in sections 50A and sections 50B across a diode-laser bar would define the locations of the vertically-aligned emitters.

Terms such as “horizontal”, “vertical”, “top-most, and “bottom-most” are used herein for convenience of description, but are not meant to limit the spatial orientation of the invention in a diode-laser device and/or during operation.

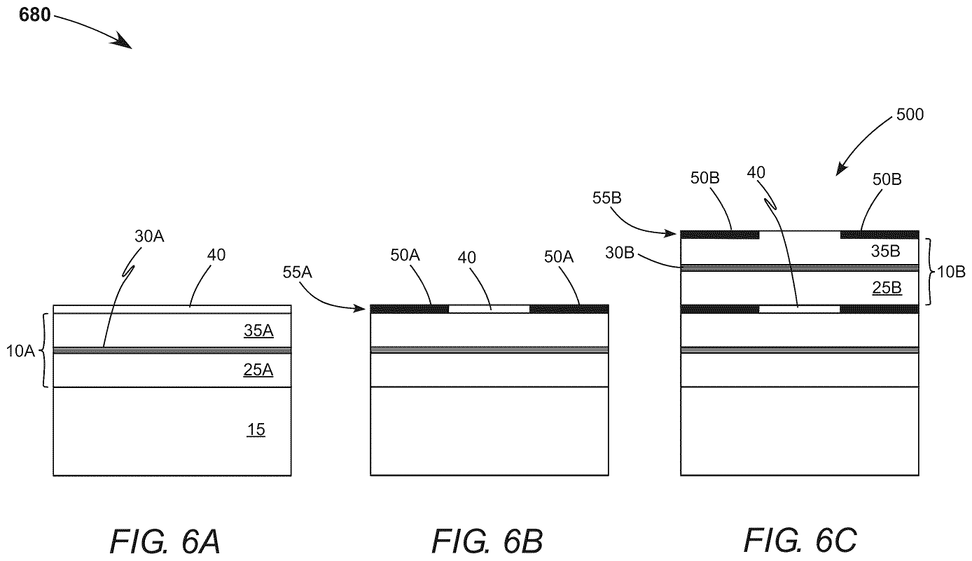

FIGS. 6A-6C schematically illustrate one method 680 for manufacturing structure 500 in accordance with the present invention. The bottom-most emitter 10A and tunneling junction 40 are epitaxially grown on n-type substrate 15 as depicted in FIG. 6A. Current confinement layer 55A is then created by selective ion implantation into tunneling junction 40 to form electrically-insulating sections 50A. For example, implantation of ions such as helium, boron, oxygen, neon, argon, silicon, phosphorus, sulfur, and germanium. It is possible to implant protons or even some metal ions, such as iron and nickel. Ion implantation creates electrical resistance by damaging the crystal structure, by changing the doping of the tunneling junction, or both. The thickness of current confinement layer 55A corresponds to the implantation depth, which may be the full thickness of tunneling junction 40, as depicted in FIG. 6B. If necessary, ion implantation may extend into p-type layer 35A, to make current confinement layer 55A even thicker. A thicker current confinement layer would have higher electrical resistance. Alternatively, sections 50A may be partially etched after ion implantation to make current confinement layer 55A thinner.

FIG. 6C depicts the complete structure 500 after epitaxially growing the top-most emitter 10B and creating current confinement layer 55B. The top-most emitter 10B is grown on sections 50A and tunneling junction 40. Sections 50B may also be created by ion implantation into p-type layer 35B. Method 680 is unorthodox because it includes two separate phases of epitaxial growth. After the first epitaxial phase, the partially grown structure is removed from the sealed and evacuated reaction chamber for ion implantation in a different tool. The incomplete structure is then returned to a reaction chamber for the second epitaxial phase. This sequence adds cost, a risk of contamination, and risk of defect formation compared to a conventional method of growing all the epitaxial layers without interruption. However, the inventors have found the performance advantages of incorporating additional current confinement more than compensate for the additional cost and effort in fabrication.

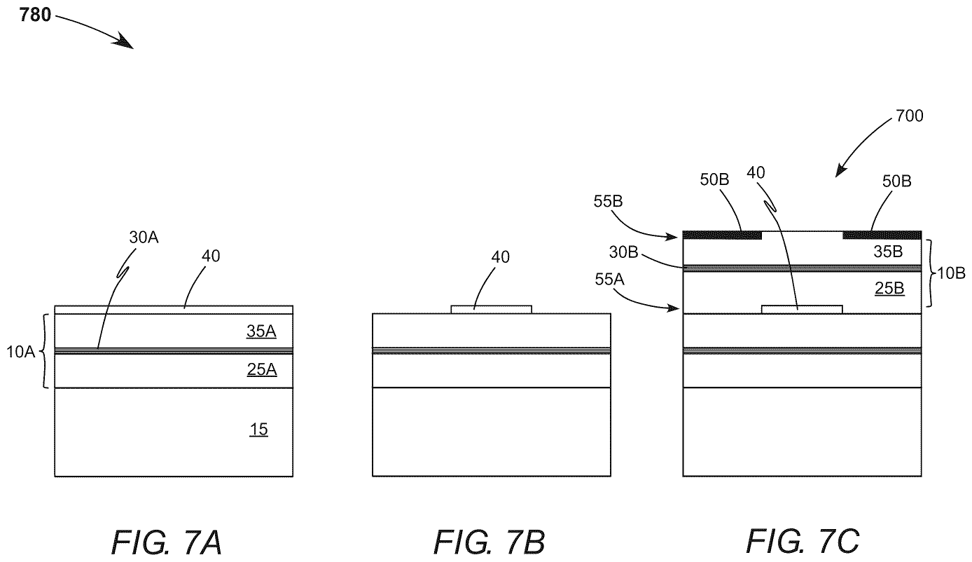

FIGS. 7A-7C schematically illustrate a method 780 for manufacturing another structure 700 in accordance with the present invention. Structure 700 depicted in FIG. 7C is similar to structure 500, however, without electrically-insulating sections 50A. Current confinement layer 55A comprises tunneling junction 40 and n-type material located laterally on each side thereof. Tunneling junction 40 has a width that is comparable to the widths of emitters 10A and 10B in operation. Current flow is spatially confined by the favorable pathway from n-type layer 25B to p-type layer 35A provided by tunneling junction 40. Current spreading is thereby minimized between active regions 30A and 30B.

FIG. 7A depicts the first phase epitaxial growth, which is the same as in method 680. FIG. 7B depicts the partially grown structure after an etching step to remove the unwanted portions of tunneling junction 40. By way of example, desired portions of tunneling junction 40 may be masked and the unwanted portions chemically etched. For example, using a dielectric or polymer photoresist mask that is a positive image of tunneling junction 40. The second phase epitaxial growth, depicted in FIG. 7C, starts on p-type layer 35A and tunneling junction 40. Otherwise, the second phase epitaxial growth is the same as in method 680.

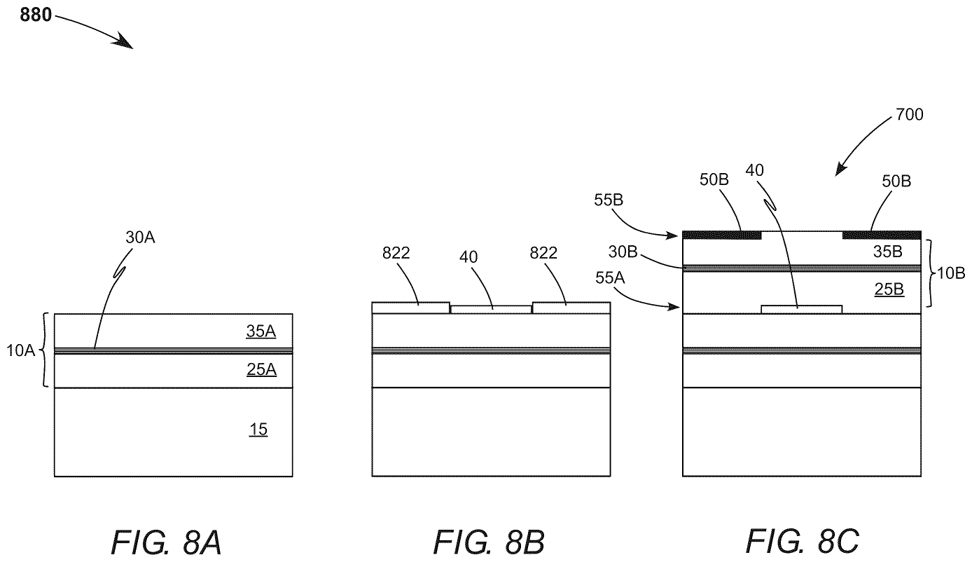

FIGS. 8A-8C schematically illustrate another method 880 for manufacturing structure 700 in accordance with the present invention. The first phase epitaxial growth is the same as in methods 680 and 780, but omits deposition of tunneling junction 40, as depicted in FIG. 8A. A mask 822 made of a dielectric material is applied to the surface of p-type layer 35A. Mask 822 is a negative image of tunneling junction 40. Mask 822 may be made of, for example, amorphous-silicon (a-Si), silicon oxide (SiO₂), silicon nitride (SiN), or alumina (Al₂O₃). Tunneling junction 40 is deposited on the unmasked sections of p-type layer 35A in a second phase epitaxial growth, as depicted in FIG. 8B. Mask 822 is then removed and tunneling junction 40 remains. The top-most emitter 10B is grown in a third epitaxial phase, which is the same as the second phase epitaxial growth in method 780.

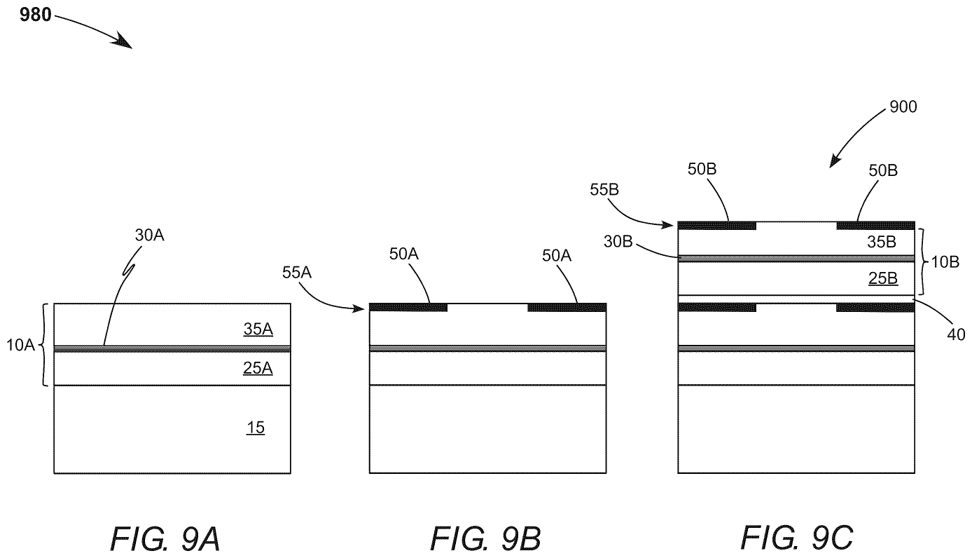

FIGS. 9A-9C schematically illustrate a method 980 for manufacturing yet another structure 900 in accordance with the present invention. Structure 900 depicted in FIG. 9C is similar to structure 500, however, tunneling junction 40 overlays current confinement layer 55A. Electrically-insulating sections 50A have p-type material laterally therebetween. The first phase epitaxial growth is the same as in method 880. Ion implantation into p-type layer 35A is then used to create electrically-insulating sections 50A of current confinement layer 55A, as depicted in FIG. 9B. The second phase epitaxial growth begins by depositing tunneling junction 40 onto p-type layer 35A and sections 50A. Tunneling junction 40 may extend across the full width of structure 900, as depicted, or may be deposited only over the gap between sections 50A. Then the top-most emitter 10B is grown and sections 50B of confinement layer 55B are created by ion implantation.

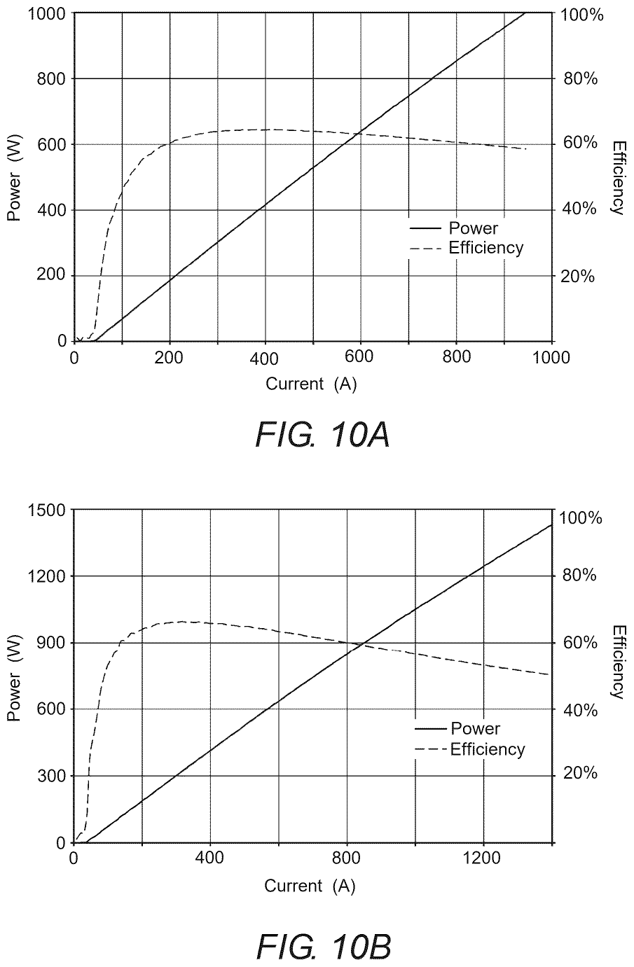

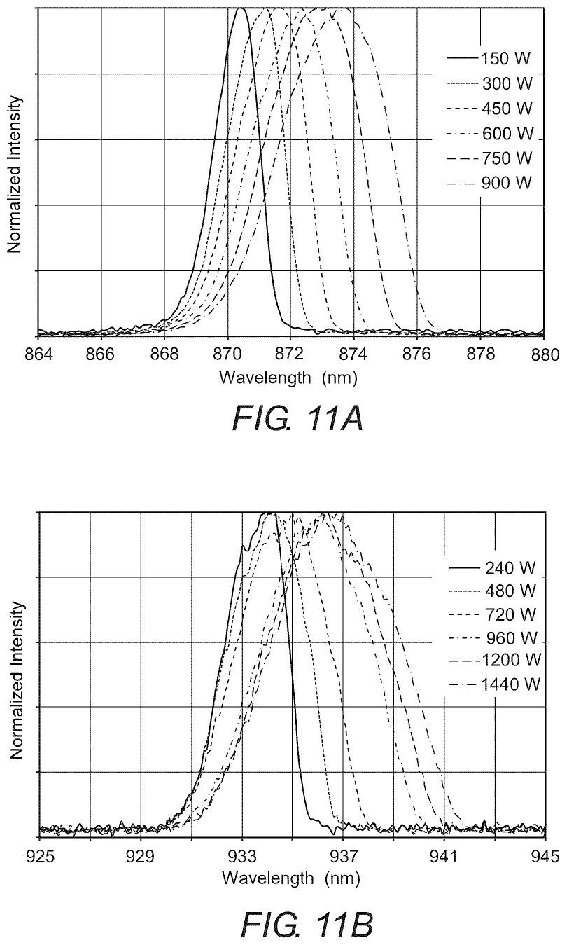

FIGS. 10A, 10B, 11A, and 11B are graphs illustrating measured performance of diode-laser bars having a single-junction structure with one active region. These graphs are presented here for comparison with the performance of diode-laser bars having double-junction structures presented herein below. The devices in FIGS. 10A, 10B, 11A, and 11B have one bar mounted in a conductively-cooled package at a temperature of 25° C. The fill factor is 75% and the resonator length is 4.0 mm. They are operated at a 2% duty cycle, with a repetition rate of 100 (hertz) Hz and a 200 microsecond (μs) pulse duration.

FIGS. 10A and 10B depict output power vs. current for devices producing 870 nanometer (nm) and 940 nm laser radiation, respectively. This data was obtained while driving just 16 emitters in each of the 48 emitter bars. The powers and currents in these graphs have been scaled to represent the performance of the full bars. The electrical power to optical power conversion efficiency is also depicted. FIGS. 11A and 11B graph the spectra of laser radiation produced by the same 870 nm and 940 nm devices, respectively, for different scaled output powers. At higher currents and output powers, the active region is at higher temperatures due to resistive heating, resulting in the observed shifting and broadening of the spectra.

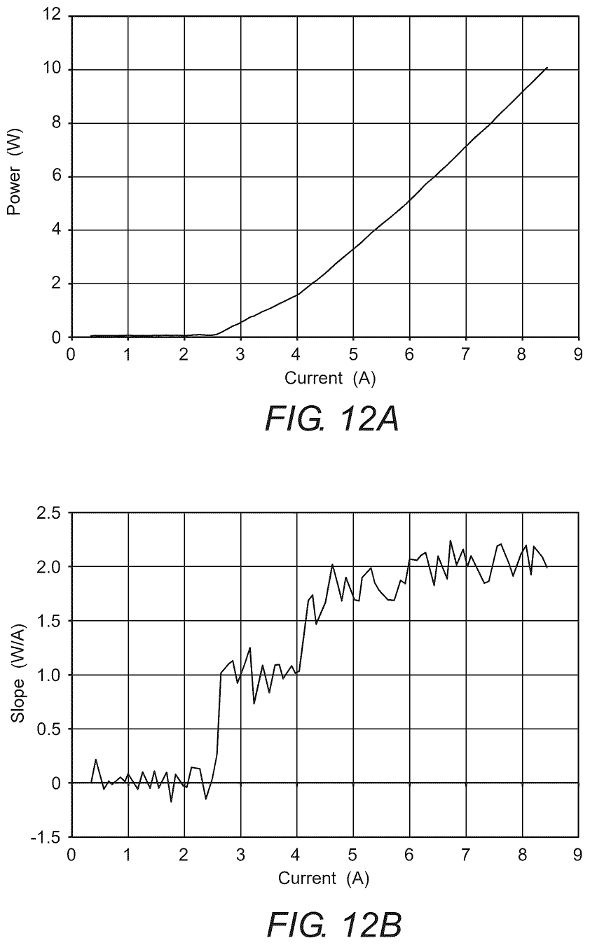

FIG. 12A is a graph illustrating measured output power vs. current for one diode-laser emitter that is equivalent to emitters in the diode-laser bar depicted in FIG. 10B, but has a double-junction structure with two active regions. The device of FIG. 12A has the structure depicted in FIG. 4, with no current confinement close to bottom-most active region 30A. The device is mounted in a conductively-cooled package. FIG. 12B is a graph illustrating the slope of the power curve in FIG. 12A vs. current. Below about 2.5 amperes (A), both emitters of the pair are below the current density threshold for lasing. Between about 2.5 and 4.2 A, just the top-most emitter is lasing with a slope of about 1 W/A. Above about 4.2 A, both emitters in a pair are lasing with a slope of about 2 W/A. In this device, in operation, the active regions of the emitters have different current densities.

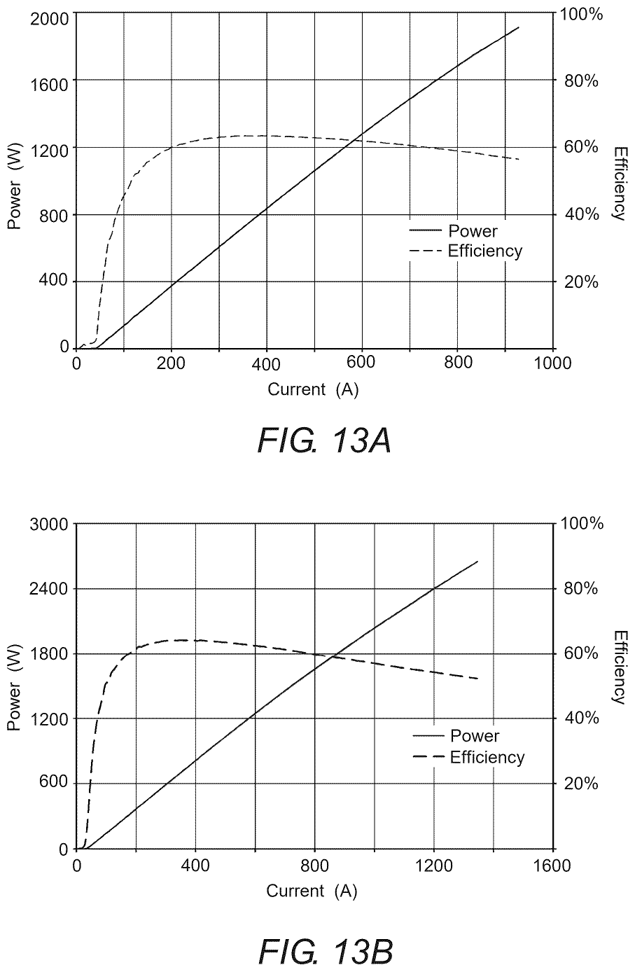

FIGS. 13A and 13B are graphs illustrating measured output power vs. current for diode-laser bars having a double-junction structure with two active regions in accordance with the present invention. Both diode-laser bars have the structure depicted in FIG. 5, with current confinement layer 55A on bottom-most emitter 10A and current confinement layer 55B on top-most emitter 10B. The conductively cooled devices of FIGS. 13A and 13B produce 870 nm and 940 nm laser radiation, respectively. The operating conditions of 25° C. temperature, 2% duty cycle, 100 Hz repetition rate, and 200 μs pulse duration are the same as in FIGS. 10A and 10B, to enable direct performance comparisons. The electrical power to optical power conversion efficiency is also graphed.

The double-junction devices of FIGS. 13A and 13B produce about twice the optical power of the single-junction devices of FIGS. 10A and 10B for the same drive current, as expected, and with comparable efficiency. The power curves in FIGS. 13A and 13B do not exhibit the inflection observed in FIG. 12A. The additional current confinement layer in the double-junction devices of FIGS. 13A and 13B ensures the same current density is maintained in the active regions of both the emitters of a pair. Therefore, both emitters start lasing at approximately the same threshold current. The power curves in FIGS. 13A and 13B verify that current spreading has been minimized in this structure, which includes both current confinement layers 55A and 55B.

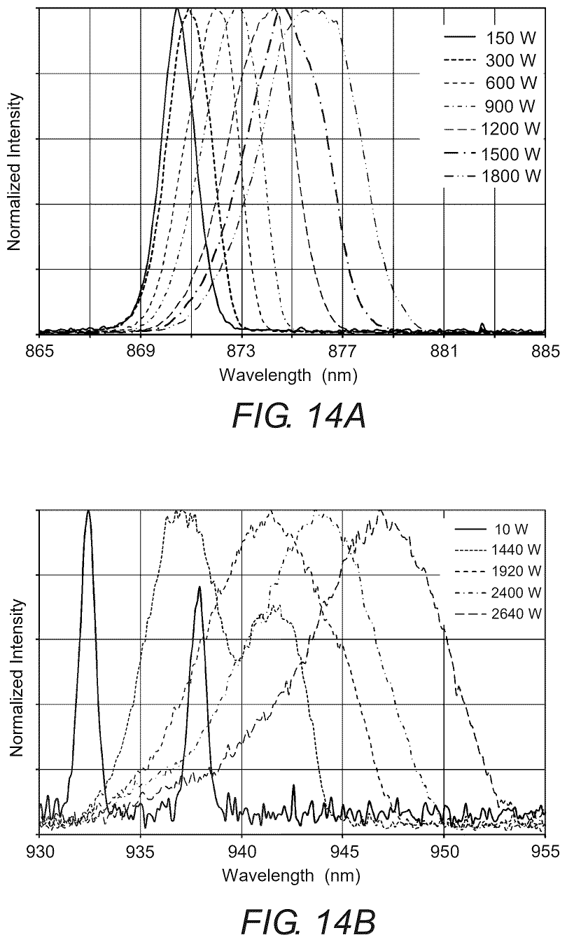

FIGS. 14A and 14B graph measured spectra of the same devices as FIGS. 13A and 13B, respectively, for different output powers. In the 870 nm device of FIG. 14A, the two emitters are relatively well matched and the laser radiation is predominantly in one spectral line at each output power. The bottom-most emitter shifts more quickly than the top-most emitter, accounting for some of the changes in line shape with output power. In the 940 nm device of FIG. 14 B, at lower output powers, the laser radiation from the bottom-most emitters and the top-most emitters appear as separate spectral lines. These separate spectral lines are about the same width. At higher output powers, the faster shifting of the bottom-most emitters results in a merging of laser radiation from all emitters into one broad spectral line. If necessary, the precise design of the heterostructures in the active layers may be modified to change a spectral separation between the emitters of a pair.

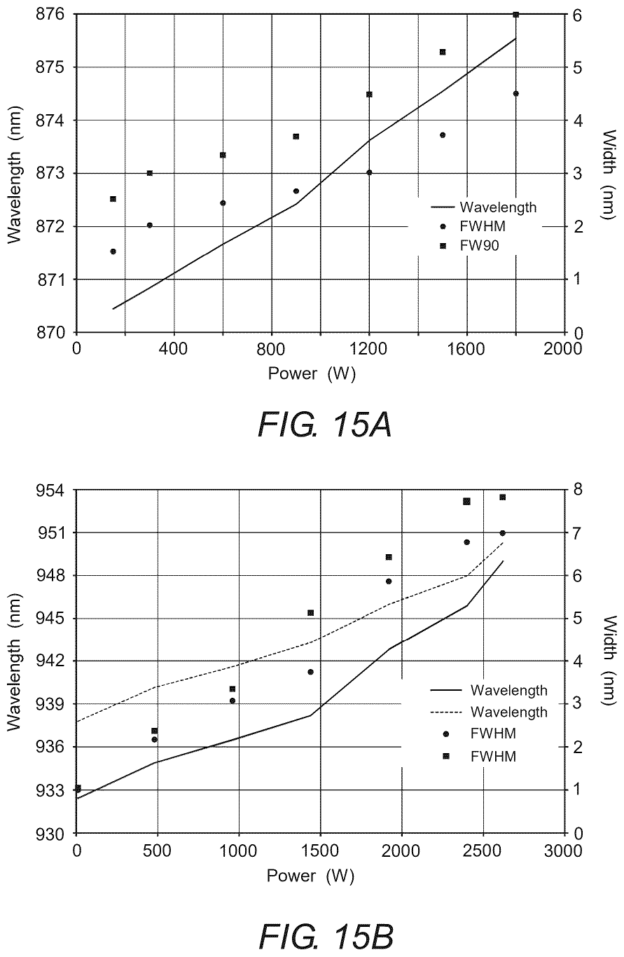

FIGS. 15A and 15B are graphs of measured spectral changes in FIGS. 14A and 14B, respectively, for the 870 nm and 940 nm devices. FIG. 15A graphs the shifting peak wavelength of the laser radiation, the full width at half maximum (FWHM) width of the spectral line, and the full width containing 90% of the power (FW90) in the spectral line. FIG. 15B graphs the shifting peak wavelengths and FWHM widths of the two spectral lines.

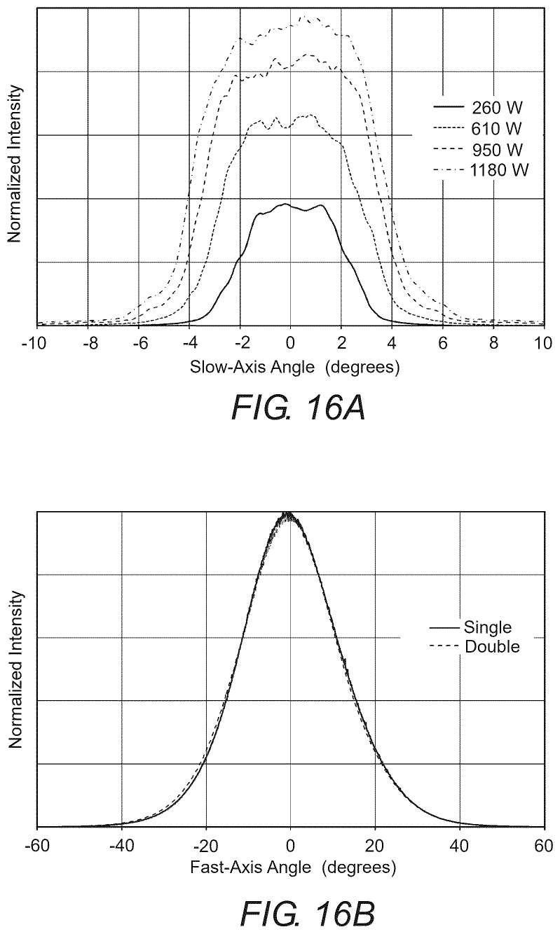

FIG. 16A is a graph of measured angular distribution of laser radiation from the 940 nm device of FIG. 13B in the far-field of the slow axis. Slow-axis angular distribution broadens with increasing current and output power. The same trend was exhibited by the equivalent single-junction device of FIG. 10B. The full width containing 95% of the power was 9.1° and the brightness was about 3.5 watts per millimeter milliradian (W/mm. mrad) at 1 kW of output power. Although the slow-axis angular width of the beam increases with current and output power, brightness also increases.

FIG. 16B is a graph comparing measured angular distributions of laser radiation in the far-field of the fast axis for the double-junction device of FIG. 13B and the equivalent single-junction device of FIG. 10B. These distributions are almost identical and mean that the inventive double-junction device with two current confinement layers may be a direct replacement for single-junction devices. Brightness and power could be scaled by about a factor of two without replacing the slow-axis and fast-axis conditioning optics. The full width containing 95% of the power was 50° at 1 kW of output power.

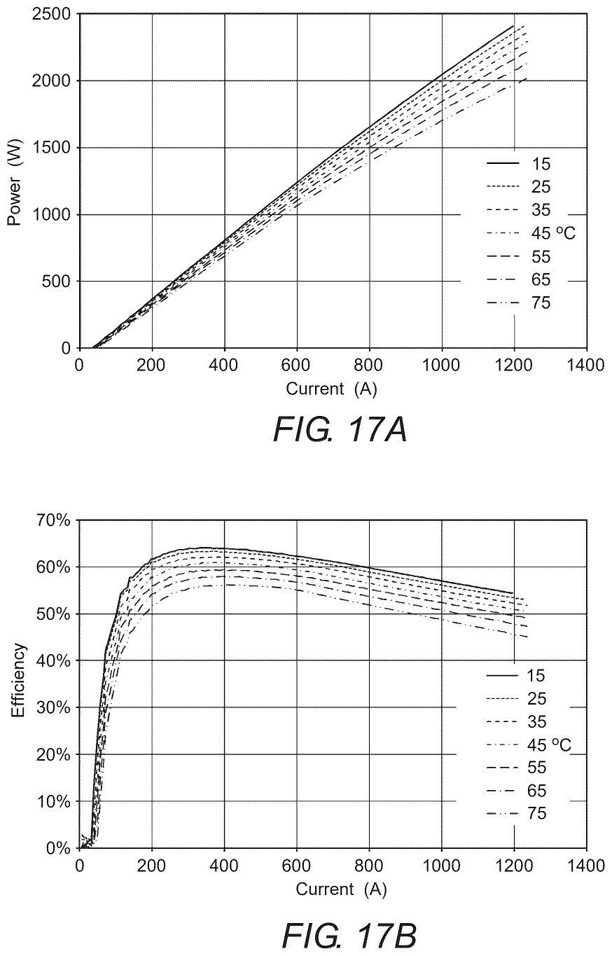

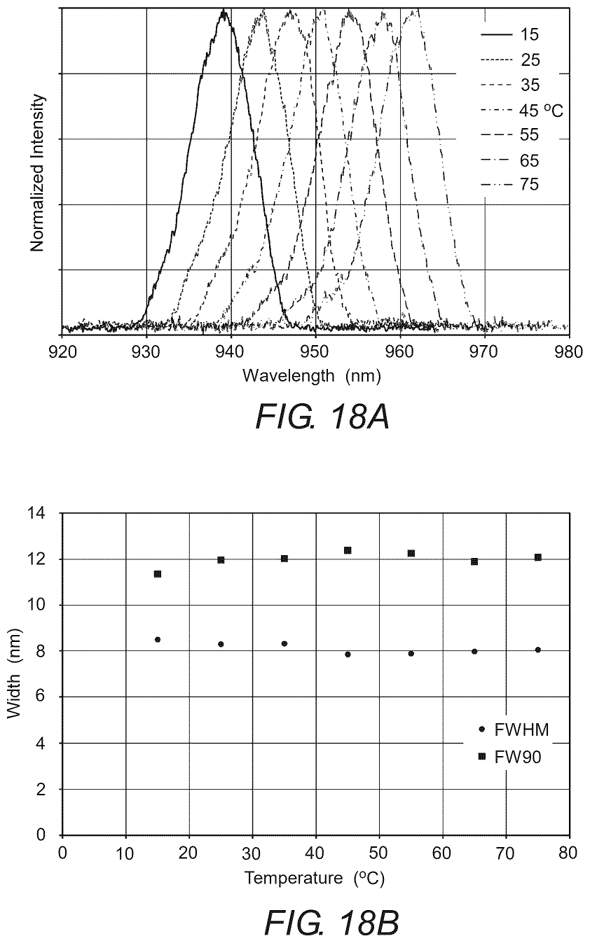

FIG. 17A is a graph illustrating measured output power vs. current for the 940 nm diode-laser bar of FIG. 13B operating at different temperatures of the conductively-cooled package. FIG. 17B is a graph illustrating measured wall-plug efficiency vs. current for the same device over the same temperature range. FIG. 18A graphs spectra of the same device over the same temperature range. FIG. 18B graphs the width of the spectral line in FIG. 18A vs. temperature. The FWHM and FW90 widths do not vary significantly with temperature.

In summary, high power and high brightness edge-emitting diode-laser bars having two or more diode-laser junctions are disclosed. Each diode-laser junction has an adjacent current confinement layer. In operation, the current confinement layers laterally constrain current flow through the semiconductor structure and maintain the same current density in the active regions of vertically-aligned emitters. Although this semiconductor structure requires multiple epitaxial growth phases, all the emitters in the diode-laser bar have the same threshold current for lasing and the same optical output power in operation. Vertical stacks of these diode-laser bars also have these advantages.

The present invention is described above in terms of a preferred embodiment and other embodiments. The invention is not limited, however, to the embodiments described and depicted herein. Rather, the invention is limited only by the claims appended hereto.

What is claimed is:

1. An edge-emitting diode-laser bar, comprising:
a plurality of n-type layers;
a plurality of p-type layers;
a plurality of active regions, each of the plurality of active regions sandwiched between an adjacent n-type layer of the plurality of n-type layers and an adjacent p-type layer of the plurality of p-type layers to form one of a plurality of diode-laser junctions, the plurality of diode-laser junctions vertically arranged on a substrate to form a semiconductor structure; and
at least one tunneling junction, adjacent diode-laser junctions having a tunneling junction located therebetween;
wherein the p-type layer of each of the plurality of diode-laser junctions is overlaid by a current confinement layer, the current confinement layers laterally constraining current flow through the semiconductor structure.

2. The edge-emitting diode-laser bar of claim 1, wherein each current confinement layer has electrically-insulating sections, current flowing through the semiconductor structure in operation being laterally confined to flow through each current confinement layer between the electrically-insulating sections.

3. The edge-emitting diode-laser bar of claim 2, wherein the electrically insulating sections are created by ion implantation.

4. The edge-emitting diode-laser bar of claim 2, wherein electrically-insulating sections of a top-most current confinement layer have p-type material laterally therebetween, current flowing into a top-most diode laser junction of the plurality of diode laser junctions through the p-type material between the electrically-insulating sections.

5. The edge-emitting diode-laser bar of claim 2, wherein electrically-insulating sections of each current confinement layer located between adjacent diode-laser junctions of the plurality of diode laser junctions have a tunneling junction laterally therebetween, current flowing between the adjacent diode-laser junctions of the plurality of diode laser junctions through the tunneling junction.

6. The edge-emitting diode-laser bar of claim 2, wherein electrically-insulating sections of each current confinement layer located between adjacent diode-laser junctions of the plurality of diode laser junctions have p-type material laterally therebetween, a tunneling junction overlaying each current confinement layer, current flowing between the adjacent diode-laser junctions through the tunneling junction and the p-type material between the electrically-insulating sections.

7. The edge-emitting diode-laser bar of claim 1, wherein each current confinement layer located between adjacent diode-laser junctions of the plurality of diode laser junctions comprises a tunneling junction and n-type material located laterally on each side of the tunneling junction, current flowing through the semiconductor structure in operation being laterally confined to flow through the tunneling junction of the current confinement layer.

8. The edge-emitting diode-laser bar of claim 7, wherein a top-most current confinement layer has electrically-insulating sections, the electrically-insulating sections having p-type material laterally therebetween, current flowing into the top-most diode layer junction through the p-type material laterally between the electrically-insulating sections.

9. The edge-emitting diode-laser bar of claim 8, wherein the electrically insulating sections are created by ion implantation.

10. The edge-emitting diode-laser bar of claim 1, wherein a plurality of emitters are horizontally arranged in a plurality of rows along the edge-emitting diode-laser bar, each row of the plurality of rows corresponding to a diode-laser junction, the emitters in different rows of the plurality of rows being vertically aligned.

11. The edge-emitting diode-laser bar of claim 10, wherein each current confinement layer has electrically-insulating sections, current flowing through the semiconductor structure in operation being laterally confined to flow through each current confinement layer between the electrically-insulating sections, wherein current density is the same in the active region of every emitter in a column of vertically-aligned emitters.

12. The edge-emitting diode-laser bar of claim 11, wherein gaps in the electrically-insulating sections along the edge-emitting diode-laser bar define the locations of the vertically-aligned emitters.

13. The edge-emitting diode-laser bar of claim 10, where in the plurality of emitters each have the same threshold current for lasing.

14. The edge-emitting diode-laser bar of claim 10, wherein a resonator length for each emitter of the plurality of emitters is defined by a distance between facets of the edge-emitting diode-laser bar.

15. The edge-emitting diode-laser bar of claim 1, wherein the semiconductor structure has two diode-laser junctions.

16. A method of making the edge-emitting diode-laser bar of claim 1, comprising the steps of:
epitaxially growing one diode-laser junction and one tunneling junction thereon;
selectively implanting ions into the one tunneling junction to create electrically insulating sections of one current confinement layer; and
epitaxially growing another diode-laser junction on the one tunneling junction and the one current confinement layer.

17. A method of making the edge-emitting diode-laser bar of claim 1, comprising the steps of:
epitaxially growing one diode-laser junction;
selectively implanting ions into the p-type layer of the one diode-laser junction to create electrically insulating sections of one current confinement layer; and
epitaxially growing one tunneling junction and another diode-laser junction on the one current confinement layer.

18. A method of making the edge-emitting diode-laser bar of claim 1, comprising the steps of:
epitaxially growing one diode-laser junction and one tunneling junction thereon;
selectively etching to remove portions of the tunneling junction to create one current confinement layer; and
epitaxially growing another diode-laser junction on the one current confinement layer.

19. A method of making the edge-emitting diode-laser bar of claim 1, comprising the steps of:
epitaxially growing one diode-laser junction;
applying a mask made of a dielectric material on the one diode-laser junction;
epitaxially growing one tunneling junction on the one diode-laser junction and the mask;
removing the mask to create one current confinement layer;
epitaxially growing another diode-laser junction on the one current confinement layer.

20. A vertical stack comprising a plurality of the edge-emitting diode-laser bars of claim 1, each of the edge-emitting diode-laser bars sandwiched between spacers made of a material that is thermally conductive and electrically conductive.
